(19) United States
(12) Patent Application Publication
(10) Pub. No.: US 2025/0266114 A1
(43) Pub. Date: Aug. 21, 2025

(54) METHODS AND APPARATUS TO DELETE AND PREVENT RECOVERY OF DATA STORED IN A MEMORY ARRAY

(71) Applicant: Intel Corporation, Santa Clara, CA (US)

(72) Inventor: Yao-Feng Chang, Gilbert, AZ (US)

(73) Assignee: Intel Corporation, Santa Clara, CA (US)

(21) Appl. No.: 19/201,248

(22) Filed: May 7, 2025

Related U.S. Application Data
(60) Provisional application No. 63/757,582, filed on Feb. 12, 2025.

(51) Int. Cl. G11C 17/18; G11C 17/12; G11C 17/16

(52) U.S. Cl. CPC G11C 17/18; G11C 17/123; G11C 17/165

(57) ABSTRACT

Methods and apparatus to delete and prevent recovery of data stored in a memory array are disclosed. An example apparatus includes machine readable instructions; and at least one programmable circuit to at least one of instantiate or execute the machine readable instructions to: obtain an instruction to zeroize a memory array; and cause a voltage to be applied across a plurality of transistors associated with a plurality of memory cells in the memory array. The voltage is to set the plurality of memory cells to a same logical value. The voltage is applied across the transistors regardless of the logical values of the plurality of memory cells prior to receiving the instruction to zeroize the memory array.

### RELATED APPLICATION

This patent claims the benefit of U.S. Provisional Patent Application No. 63/757,582, which was filed on Feb. 12, 2025. U.S. Provisional Patent Application No. 63/757,582 is hereby incorporated herein by reference in its entirety. Priority to U.S. Provisional Patent Application No. 63/757,582 is hereby claimed.

### BACKGROUND

Read-only memory (ROM) is a type of memory that stores data permanently (or semi-permanently) and generally cannot be modified once written. In some cases, the stored data is written into the memory at the time of (e.g., during) manufacturing the ROM. In other cases, the stored data can be written or programmed into the memory after manufacturing the ROM. However, in such cases, data can usually only be written once after which time it typically cannot be modified. This latter type of ROM is sometimes referred to as one-time programmable (OTP) ROM.

### BRIEF DESCRIPTION OF THE DRAWINGS

FIG. 1 is a block diagram of an example environment in which an example controller operates to analyze a software application under test.

FIG. 2 is a top view of an example implementation of the example memory cell of FIG. 1.

FIG. 3 is a block diagram of an example implementation of the controller of FIG. 1.

FIG. 4 is a flowchart representative of example machine readable instructions and/or example operations that may be executed, instantiated, and/or performed by example programmable circuitry to implement the controller of FIG. 2.

FIG. 5 is a block diagram of an example processing platform including programmable circuitry structured to execute, instantiate, and/or perform the example machine readable instructions and/or perform the example operations of FIG. 4 to implement the controller of FIG. 2.

FIG. 6 is a block diagram of an example implementation of the programmable circuitry of FIG. 5.

FIG. 7 is a block diagram of another example implementation of the programmable circuitry of FIG. 5.

FIG. 8 is a block diagram of an example software/firmware/instructions distribution platform (e.g., one or more servers) to distribute software, instructions, and/or firmware (e.g., corresponding to the example machine readable instructions of FIG. 4) to client devices associated with end users and/or consumers (e.g., for license, sale, and/or use), retailers (e.g., for sale, re-sale, license, and/or sub-license), and/or original equipment manufacturers (OEMs) (e.g., for inclusion in products to be distributed to, for example, retailers and/or to other end users such as direct buy customers).

In general, the same reference numbers will be used throughout the drawing(s) and accompanying written description to refer to the same or like parts. The figures are not necessarily to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

### DETAILED DESCRIPTION

One-time programmable (OTP) read-only memory (ROM, or PROM) continues to be an important technology among embedded memory categories. New product applications, such as reconfigurable ROM, root-of-trust implementations (memory redundancy), on-chip security keys, and unit-level-traceability need OTP ROM to support high density, reliable, available, and affordable information storage. Furthermore, the ability to delete or erase data is important in many settings, particularly when sensitive information or security concerns are involved (e.g., where the data to be erased includes cryptographic keys, critical security parameters, and/or other sensitive information). Deleting or erasing data can be a challenge when the data is stored in read-only memory (ROM) because ROM is designed to not be overwritten.

One approach to deleting electronically stored data is known as the process of zeroization (e.g., to zeroize memory). Zeroization is accomplished by altering or deleting the contents of the data storage to prevent recovery of the data. This process is required by the National Institute of Standards and Technology (NIST) for cryptographic modules. The name of “zeroization” for this process is based on an implementation in which every bit of data stored in memory is switched to or assigned a value of 0. However, as used herein, zeroization, zeroize, and other variations of the terms includes altering memory bits in ways other than switching all bits to a value of 0. For instance, as used herein, zeroization may include switching all bits to a value of 0, switching all bits to a value of 1, switching some bits to a value of 0 and some bits to a value of 1, switching to another value if the memory supports other values, etc.

Examples disclosed herein implement memory cells in ROM with an antifuse element to perform zeroization. As used herein, an antifuse element or an antifuse device is a circuit component that initially inhibits the passage of current until it is tripped after which current is able to pass through with little resistance. That is, an antifuse device, as its name implies, is the opposite of an electronic fuse (efuse) element or fuse device that initially allows current to pass through until it is tripped and then it prevents the passage of current. In other words, a fuse starts as a closed circuit until it is tripped at which point it becomes an open circuit, whereas an antifuse device starts as an open circuit until it is tripped at which point it becomes a closed circuit.

In examples disclosed herein, the antifuse device is implemented by a transistor with a relatively thin gate oxide (e.g., thinner than the gate oxide used in other transistors in the circuit). The gate oxide, as a dielectric, acts as an open circuit to prevent the passage of current. However, when a sufficiently high voltage is applied to the transistor, dielectric breakdown occurs in the gate oxide and it becomes a conductor, thereby changing from an open circuit to a closed circuit. In this manner, a transistor with a thin gate oxide can be used as an antifuse device to control the programming of a memory cell as it is changed from a 0 to a 1. Unlike efuse elements used in known memory cells, such antifuse devices can be subject to multiple pulse programming without concern. Thus, example memory disclosed herein based on antifuse technology can significantly reduce yield loss relative to efuse implementations. Further, inasmuch as multiple pulse programming is possible for antifuse devices, a signal to assign each bit in memory to 1 as part of a zeroization process can be provided to every bit cell in a memory array regardless of whether the bit cell was previously programmed to a value of 1 or still at a value of 0. As a result, the process of zeroization is significantly less complex than it is for efuse implementations discussed above because there is no need to pre-read the memory array to identify and/or isolate specific bits that need to be switched from a value of 0 to a value of 1 while avoiding other bits that are already assigned a value of 1. This also means there is no need for complex circuitry, thereby allowing for larger arrays with more memory cells to be included on a semiconductor die of a given size. Further still, the dielectric breakdown of the gate oxide does not leave any changes to the circuitry that are visible using typical reverse-engineering techniques (e.g., SEM and TEM imaging).

Additionally, antifuse technology disclosed herein have relatively low current requirements (e.g., less than 1 milliamp, less than 100 microamps, etc.). Further, antifuse devices are associated with a longer sensing lifetime than efuse devices, thereby enabling improvements to RAM power. Another advantage of antifuse devices is their relatively small size as compared to efuse devices. For instance, example memory cells disclosed herein that include a transistor implemented as an antifuse device can be 1 square micrometer or less (e.g., less than or equal to approximately 0.5 square micrometers, less than or equal to approximately 0.255 square micrometers, etc.). By contrast, known efuse devices are nearly 5 square micrometers. Inasmuch as example memory cells disclosed herein are approximately twenty times smaller than memory cells based on efuse technology, examples disclosed herein can implement memory with a much higher density. For instance, known efuse technology can achieve a density resulting in one megabit of memory implemented in an area of less than 171 square millimeters and as low as 56 square millimeters. By contrast, examples disclosed herein can implement one megabit of memory within an area of less than 20 square millimeters and as low as 5.6 square millimeters or less.

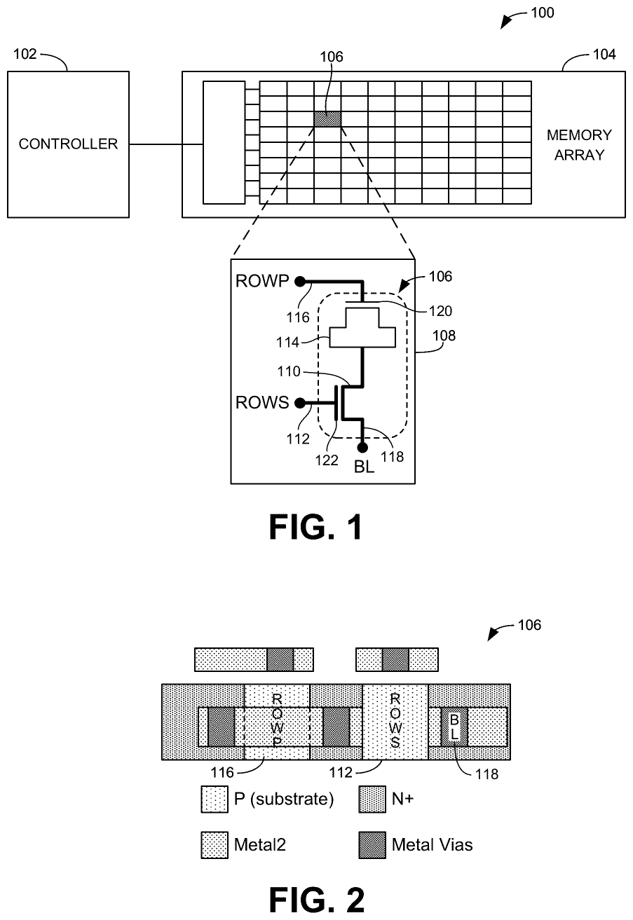

FIG. 1 is a block diagram of an example environment 100 in which an example controller 102 (e.g., a zeroization controller) is implemented to delete or erase and prevent the recovery of data stored in an example memory array 104. In some examples, the controller 102 and the memory array 104 are implemented on a single semiconductor (e.g., silicon) die (e.g., a semiconductor chip, an integrated circuit (IC), etc.). In some examples, the controller 102 is implemented in a separate piece of semiconductor to that of the memory array 104. However, in some such examples, the controller 102 and the memory array 104 are included in a common package.

In this example, the memory array 104 is a one-time programmable (OTP) read-only memory (ROM), also known as programmable ROM (PROM). However, in some examples, the memory array 104 can be implemented by any other suitable type of memory technology. In the illustrated example, the memory array 104 includes a plurality of memory cells 106 (e.g., bit cells) arranged in rows (e.g., word lines) and columns (bit lines). FIG. 1 includes an enlarged image 108 that diagrammatically represents the circuitry included within one of the memory cells 106. FIG. 2 is a top view of an example layout of the example memory cell 106 of FIG. 1 on a semiconductor substrate. Circuitry of other memory cells 106 in the memory array 104 are similarly constructed to the memory cell 106 shown in the enlarged image 108 and detailed in FIG. 2.

As represented in the enlarged image 108 in FIG. 1, the example memory cell 106 includes two-transistor transition-free dual-oxide bit cell topology. A first transistor 110 is electrically coupled to a selection row (ROWS) word line 112 and the second transistor 114 is electrically coupled to a programming row (ROWP) word line 116. The first transistor 110 is also referred to herein as an access transistor because, as shown in the illustrated example, the first transistor 110 provides access to (e.g., operates as a switch for) the second transistor along an associated bit line 118. The second transistor 114 is also referred to herein as a memory transistor because the state of the second transistor is what stores the single bit of memory associated with the memory cell 106. More particularly, the value of the bit cell is defined based on the state of a gate oxide associated with the gate 120. When the gate oxide maintains its dielectric properties of being electrically insulative, current will not be able to pass through the second transistor from the ROWP word line 116 along the bit line 118 resulting in a logical low (associated with a value of 0) when the second transistor 114 is sensed or read. By contrast, if the gate oxide of the gate 120 has undergone dielectric breakdown to become conductive, current can pass through the second transistor 114 resulting in a logical high (associated with a value of 1) when the second transistor 114 is sensed or read.

In some examples, the state of the gate oxide associated with the gate 120 of the second transistor 114 is caused to undergo dielectric breakdown through the application of a relatively high voltage across the second transistor 114. More particularly, the voltage to be applied needs to meet or exceed the breakdown voltage of the gate oxide. The voltage at which this occurs for a given material is a function of the dielectric strength of the material as well as the size and shape of the material. For instance, a thinner dielectric will have a lower breakdown voltage than a thicker dielectric. Accordingly, in some examples, the gate oxide of the second transistor 114 is thinner than the gate oxide associated with a gate 122 of the first transistor 110. This is represented in FIG. 1 based on the thinner lines used for the second transistor 114 as compared with the thicker lines used for the first transistor 110. In some examples, the gate oxide in the first transistor 110 is multiple times (e.g., twice, three times, four times, etc.) the thickness of the gate oxide in the second transistor 114. For instance, in some examples, the thickness of the gate oxide in the first transistor 110 is approximately 3 nanometers and the gate oxide in the second transistor 114 is approximately 0.5 nanometers. In some examples, the thickness of the gate oxide in the first transistor 110 can be more or less than 3 nanometers and/or the thickness of the gate oxide in the second transistor 114 can be more or less than 0.5 nanometers. In some such examples, the difference between the gate oxide thickness is approximately 2.5 nanometers. However, in other examples, the difference can be more or less than 2.5 nanometers.

The different thicknesses of gate oxide in the two transistors 110, 114 results in the gate oxide in the second transistor 114 breaking down sooner (e.g., at lower voltages) than the gate oxide in the first transistor 110. In this manner, the state of the gate oxide within the second transistor 114 can be changed from an insulator to a conductor (thereby changing the logical value stored by the second transistor 114) without affecting the insulative state of the gate oxide in the first transistor 110.

The second transistor is also referred to herein as an antifuse device because it performs the function of such a device. That is, as described above, the second transistor 114 initial acts as an open circuit that prevents the passage of current (due to the insulative properties of the gate oxide). However, once the gate oxide has undergone dielectric breakdown, the second transistor 114 acts as a closed circuit to allow passage of current.

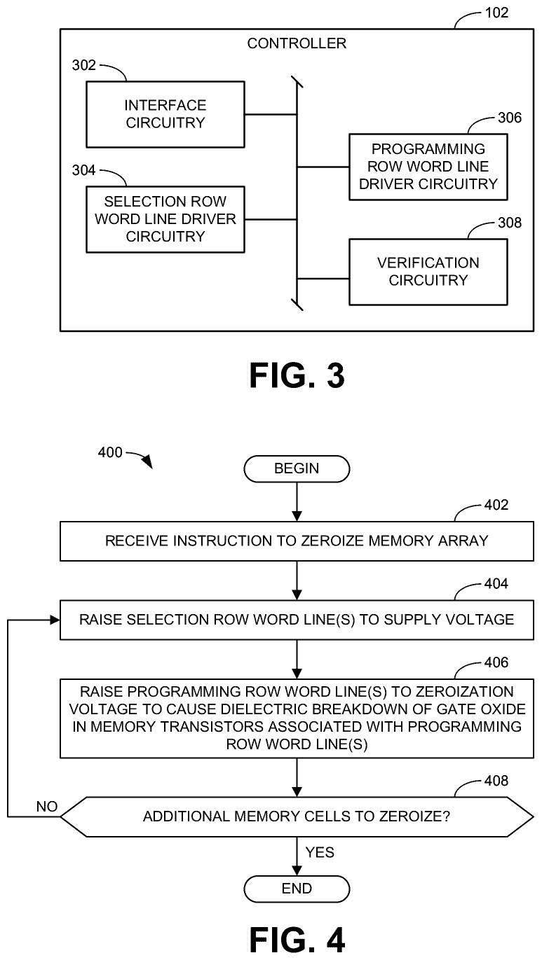

In some examples, the controller 102 causes a relatively high voltage to be applied across the second transistor 114 of every memory cell 106 in the memory array 104 to cause dielectric breakdown of the thin gate oxide in such transistors. In this manner, zeroization is achieved by switching the logical value associated with every memory cell 106 to 1. As a result, the data previously stored in the memory array 104 is deleted and cannot be recovered. In some examples, some of the memory cells 106 may have already been programmed to a value of 1. However, in some such examples, the controller 102 still causes an electrical signal to be sent to such memory cells 106 for purposes of simplicity because, unlike for efuse technology, there is no harm in transmitting such a signal across the second transistor 114 with an oxide layer that that has already broken down and been converted from an insulator to a conductor. An example implementation of the controller 102 is described in conjunction with FIG. 3 and the flowchart of FIG. 4.

FIG. 3 is a block diagram of an example implementation of the controller 102 of FIG. 1 to delete or erase and prevent the recovery of data stored in the example memory array 104 of FIG. 1. The controller 102 of FIG. 3 may be instantiated (e.g., creating an instance of, bring into being for any length of time, materialize, implement, etc.) by programmable circuitry such as a Central Processor Unit (CPU) executing first instructions, a field programmable gate array, a programmable logic device (PLD), a generic array logic (GAL) device, a programmable array logic (PAL) device, a complex programmable logic device (CPLD), a simple programmable logic device (SPLD), a microcontroller (MCU), a programmable system on chip (PSoC), etc. Additionally or alternatively, the controller 102 of FIG. 3 may be instantiated (e.g., creating an instance of, bring into being for any length of time, materialize, implement, etc.) by (i) an Application Specific Integrated Circuit (ASIC) and/or (ii) a Field Programmable Gate Array (FPGA) structured and/or configured in response to execution of second instructions to perform operations corresponding to the first instructions. It should be understood that some or all of the circuitry of FIG. 3 may, thus, be instantiated at the same or different times. Some or all of the circuitry of FIG. 3 may be instantiated, for example, in one or more threads executing concurrently on hardware and/or in series on hardware. Moreover, in some examples, some or all of the circuitry of FIG. 3 may be implemented by microprocessor circuitry executing instructions and/or FPGA circuitry performing operations to implement one or more virtual machines and/or containers.

The example controller 102 of FIG. 3 includes example interface circuitry 302, example selection row word line driver circuitry 304, example programming row word line driver circuitry 306, and example verification circuitry 308.

The example interface circuitry 302 enables the controller 102 to receive a request and/or command to zeroize the memory array 104. In some examples, the request and/or command is provided by a user. In some examples, the request and/or command is automatically generated in response to certain conditions being satisfies. In some examples, the interface circuitry 302 is instantiated by programmable circuitry executing interface instructions and/or configured to perform operations such as those represented by the flowchart(s) of FIG. 4.

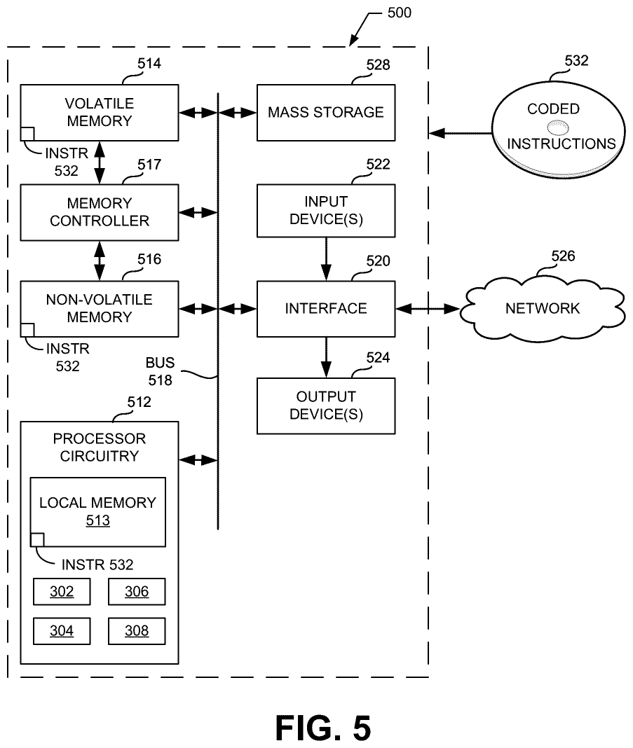

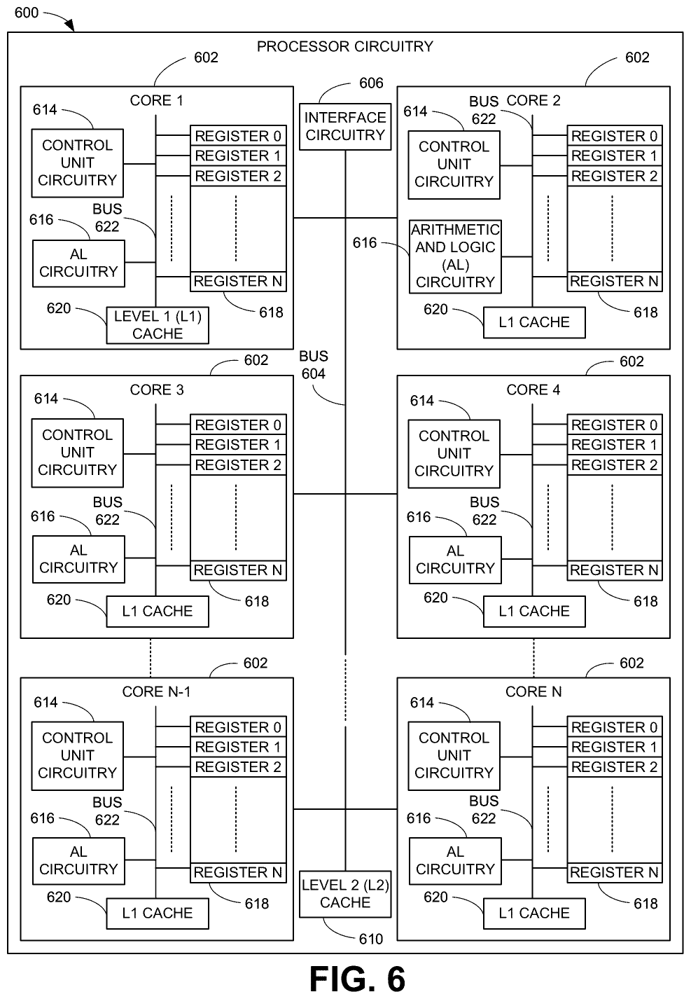

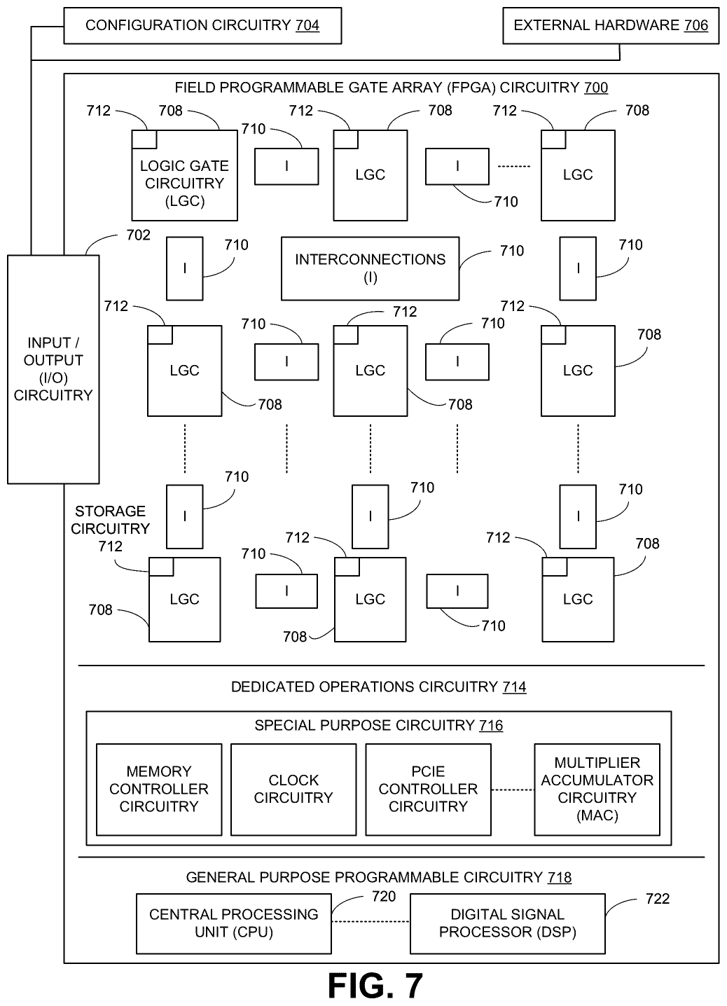

In some examples, the controller 102 includes means for interfacing with external components. For example, the means for interfacing may be implemented by interface circuitry 302. In some examples, the interface circuitry 302 may be instantiated by programmable circuitry such as the example programmable circuitry 512 of FIG. 5. For instance, the interface circuitry 302 may be instantiated by the example microprocessor 600 of FIG. 6 executing machine executable instructions such as those implemented by at least block 402 of FIG. 4. In some examples, the interface circuitry 302 may be instantiated by hardware logic circuitry, which may be implemented by an ASIC, XPU, or the FPGA circuitry 700 of FIG. 7 configured and/or structured to perform operations corresponding to the machine readable instructions. Additionally or alternatively, the interface circuitry 302 may be instantiated by any other combination of hardware, software, and/or firmware. For example, the interface circuitry 302 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

The example selection row word line driver circuitry 304 enables the controller 102 to select memory cells 106 in a given row to be zeroized by causing a supply voltage to be applied across the access transistor 110 associated with the corresponding memory cells 106. In some examples, the selection row word line driver circuitry 304 causes the supply voltage to be provided to multiple different rows (e.g., word lines) concurrently. In some examples, the selection row word line driver circuitry 304 is instantiated by programmable circuitry executing selection row word line driver instructions and/or configured to perform operations such as those represented by the flowchart(s) of FIG. 4.

In some examples, the controller 102 includes means for selecting memory cells. For example, the means for selecting may be implemented by the selection row word line driver circuitry 304. In some examples, the selection row word line driver circuitry 304 may be instantiated by programmable circuitry such as the example programmable circuitry 512 of FIG. 5. For instance, the selection row word line driver circuitry 304 may be instantiated by the example microprocessor 600 of FIG. 6 executing machine executable instructions such as those implemented by at least block 404 of FIG. 4. In some examples, the selection row word line driver circuitry 304 may be instantiated by hardware logic circuitry, which may be implemented by an ASIC, XPU, or the FPGA circuitry 700 of FIG. 7 configured and/or structured to perform operations corresponding to the machine readable instructions. Additionally or alternatively, the selection row word line driver circuitry 304 may be instantiated by any other combination of hardware, software, and/or firmware. For example, the selection row word line driver circuitry 304 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

The example programming row word line driver circuitry 306 enables the controller 102 to force the memory transistors 114 associated with selected access transistors 110 to switch to a value of 1 by causing the gate oxide in the memory transistors 114 to undergo dielectric breakdown. More particularly, in some examples, the programming row word line driver circuitry 306 causes a zeroization voltage to be applied across the memory transistor 114. In some examples, the zeroization voltage is higher than the supply voltage. For instance, in some examples, the supply voltage is approximately 1.8 volts and the zeroization voltage is approximately 5 volts. As discussed above, the zeroization voltage is equal to or greater than the breakdown voltage of the gate oxide in the memory transistor 114. However, the zeroization voltage is less than the breakdown voltage of the gate oxide in the access transistor 110 because the gate oxide is thicker in the access transistor 110 than it is in the memory transistor 114. In some examples, the programming row word line driver circuitry 306 is instantiated by programmable circuitry executing programming row word line driver instructions and/or configured to perform operations such as those represented by the flowchart(s) of FIG. 4.

In some examples, the controller 102 includes means for programming a memory transistor. For example, the means for programming may be implemented by the programming row word line driver circuitry 306. In some examples, the programming row word line driver circuitry 306 may be instantiated by programmable circuitry such as the example programmable circuitry 512 of FIG. 5. For instance, the programming row word line driver circuitry 306 may be instantiated by the example microprocessor 600 of FIG. 6 executing machine executable instructions such as those implemented by at least blocks 406 of FIG. 4. In some examples, the programming row word line driver circuitry 306 may be instantiated by hardware logic circuitry, which may be implemented by an ASIC, XPU, or the FPGA circuitry 700 of FIG. 7 configured and/or structured to perform operations corresponding to the machine readable instructions. Additionally or alternatively, the programming row word line driver circuitry 306 may be instantiated by any other combination of hardware, software, and/or firmware. For example, the programming row word line driver circuitry 306 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

The example verification circuitry 308 determines whether the memory cells 106 have been properly zeroized by checking whether all memory bit values have been switched to a value of 1. In some examples, the verification circuitry 308 achieves this by reading or sensing every memory bit. In some examples, the verification circuitry 308 is omitted. In some examples, the verification circuitry 308 is instantiated by programmable circuitry executing verification instructions and/or configured to perform operations such as those represented by the flowchart(s) of FIG. 4.

In some examples, the controller 102 includes means for verifying zeroization of a memory cell. For example, the means for determining may be implemented by the verification circuitry 308. In some examples, the verification circuitry 308 may be instantiated by programmable circuitry such as the example programmable circuitry 512 of FIG. 5. For instance, the verification circuitry 308 may be instantiated by the example microprocessor 600 of FIG. 6 executing machine executable instructions such as those implemented by at least blocks 408 of FIG. 4. In some examples, the verification circuitry 308 may be instantiated by hardware logic circuitry, which may be implemented by an ASIC, XPU, or the FPGA circuitry 700 of FIG. 7 configured and/or structured to perform operations corresponding to the machine readable instructions. Additionally or alternatively, the verification circuitry 308 may be instantiated by any other combination of hardware, software, and/or firmware. For example, the verification circuitry 308 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

In some examples, the example interface circuitry 302, the example selection row word line driver circuitry 304, the example programming row word line driver circuitry 306, and the example verification circuitry 308 may be instantiated by programmable circuitry such as the example programmable circuitry 512 of FIG. 5. For instance, the example interface circuitry 302, the example selection row word line driver circuitry 304, the example programming row word line driver circuitry 306, and the example verification circuitry 308 may be instantiated by the example microprocessor 600 of FIG. 6 executing machine executable instructions such as those implemented by the blocks of FIG. 4. In some examples, the example interface circuitry 302, the example selection row word line driver circuitry 304, the example programming row word line driver circuitry 306, and the example verification circuitry 308 may be instantiated by hardware logic circuitry, which may be implemented by an ASIC, XPU, or the FPGA circuitry 700 of FIG. 7 configured and/or structured to perform operations corresponding to the machine readable instructions. Additionally or alternatively, the example interface circuitry 302, the example selection row word line driver circuitry 304, the example programming row word line driver circuitry 306, and the example verification circuitry 308 may be instantiated by any other combination of hardware, software, and/or firmware. For example, the example interface circuitry 302, the example selection row word line driver circuitry 304, the example programming row word line driver circuitry 306, and the example verification circuitry 308 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

While an example manner of implementing the controller 102 of FIG. 1 is illustrated in FIG. 3, one or more of the elements, processes, and/or devices illustrated in FIG. 3 may be combined, divided, re-arranged, omitted, eliminated, and/or implemented in any other way. Further, the example interface circuitry 302, the example selection row word line driver circuitry 304, the example programming row word line driver circuitry 306, the example verification circuitry 308, and/or, more generally, the example controller 102 of FIG. 3, may be implemented by hardware alone or by hardware in combination with software and/or firmware. Thus, for example, any of the example interface circuitry 302, the example selection row word line driver circuitry 304, the example programming row word line driver circuitry 306, the example verification circuitry 308, and/or, more generally, the example controller 102, could be implemented by programmable circuitry in combination with machine readable instructions (e.g., firmware or software), processor circuitry, analog circuit(s), digital circuit(s), logic circuit(s), programmable processor(s), programmable microcontroller(s), graphics processing unit(s) (GPU(s)), digital signal processor(s) (DSP(s)), ASIC(s), programmable logic device(s) (PLD(s)), and/or field programmable logic device(s) (FPLD(s)) such as FPGAs. Further still, the example controller 102 of FIG. 3 may include one or more elements, processes, and/or devices in addition to, or instead of, those illustrated in FIG. 3, and/or may include more than one of any or all of the illustrated elements, processes and devices.

A flowchart representative of example machine readable instructions, which may be executed by programmable circuitry to implement and/or instantiate the controller 102 of FIG. 3 and/or representative of example operations which may be performed by programmable circuitry to implement and/or instantiate the controller 102 of FIG. 3, are shown in FIG. 4. The machine readable instructions may be one or more executable programs or portion(s) of one or more executable programs for execution by programmable circuitry such as the programmable circuitry 512 shown in the example processor platform 500 discussed below in connection with FIG. 5 and/or may be one or more function(s) or portion(s) of functions to be performed by the example programmable circuitry (e.g., an FPGA) discussed below in connection with FIGS. 6 and/or 7. In some examples, the machine readable instructions cause an operation, a task, etc., to be carried out and/or performed in an automated manner in the real world. As used herein, “automated” means without human involvement.

The program may be embodied in instructions (e.g., software and/or firmware) stored on one or more non-transitory computer readable and/or machine readable storage medium such as cache memory, a magnetic-storage device or disk (e.g., a floppy disk, a Hard Disk Drive (HDD), etc.), an optical-storage device or disk (e.g., a Blu-ray disk, a Compact Disk (CD), a Digital Versatile Disk (DVD), etc.), a Redundant Array of Independent Disks (RAID), a register, ROM, a solid-state drive (SSD), SSD memory, non-volatile memory (e.g., electrically erasable programmable read-only memory (EEPROM), flash memory, etc.), volatile memory (e.g., Random Access Memory (RAM) of any type, etc.), and/or any other storage device or storage disk. The instructions of the non-transitory computer readable and/or machine readable medium may program and/or be executed by programmable circuitry located in one or more hardware devices, but the entire program and/or parts thereof could alternatively be executed and/or instantiated by one or more hardware devices other than the programmable circuitry and/or embodied in dedicated hardware. The machine readable instructions may be distributed across multiple hardware devices and/or executed by two or more hardware devices (e.g., a server and a client hardware device). For example, the client hardware device may be implemented by an endpoint client hardware device (e.g., a hardware device associated with a human and/or machine user) or an intermediate client hardware device gateway (e.g., a radio access network (RAN)) that may facilitate communication between a server and an endpoint client hardware device. Similarly, the non-transitory computer readable storage medium may include one or more mediums. Further, although the example program is described with reference to the flowchart illustrated in FIG. 4, many other methods of implementing the example controller 102 may alternatively be used. For example, the order of execution of the blocks of the flowchart may be changed, and/or some of the blocks described may be changed, eliminated, or combined. Additionally or alternatively, any or all of the blocks of the flow chart may be implemented by one or more hardware circuits (e.g., processor circuitry, discrete and/or integrated analog and/or digital circuitry, an FPGA, an ASIC, a comparator, an operational-amplifier (op-amp), a logic circuit, etc.) structured to perform the corresponding operation without executing software or firmware. The programmable circuitry may be distributed in different network locations and/or local to one or more hardware devices (e.g., a single-core processor (e.g., a single core CPU), a multi-core processor (e.g., a multi-core CPU, an XPU, etc.)). As used herein, programmable circuitry includes any type(s) of circuitry that may be programmed to perform a desired function such as, for example, a CPU and/or an FPGA. The programmable circuitry may include one or more CPUs and/or one or more FPGAs located in the same package (e.g., the same integrated circuit (IC) package or in two or more separate housings), one or more CPUs and/or one or more FPGAs in a single machine, multiple CPUs and/or FPGAs distributed across multiple servers of a server rack, and/or multiple CPUs and/or FPGAs distributed across one or more server racks. Additionally or alternatively, programmable circuitry may include a programmable logic device (PLD), a generic array logic (GAL) device, a programmable array logic (PAL) device, a complex programmable logic device (CPLD), a simple programmable logic device (SPLD), a microcontroller (MCU), a programmable system on chip (PSoC), etc., and/or any combination(s) thereof in any of the contexts explained above.

The machine readable instructions described herein may be stored in one or more of a compressed format, an encrypted format, a fragmented format, a compiled format, an executable format, a packaged format, etc. Machine readable instructions as described herein may be stored as data (e.g., computer-readable data, machine-readable data, one or more bits (e.g., one or more computer-readable bits, one or more machine-readable bits, etc.), a bitstream (e.g., a computer-readable bitstream, a machine-readable bitstream, etc.), etc.) or a data structure (e.g., as portion(s) of instructions, code, representations of code, etc.) that may be utilized to create, manufacture, and/or produce machine executable instructions. For example, the machine readable instructions may be fragmented and stored on one or more storage devices, disks and/or computing devices (e.g., servers) located at the same or different locations of a network or collection of networks (e.g., in the cloud, in edge devices, etc.). The machine readable instructions may require one or more of installation, modification, adaptation, updating, combining, supplementing, configuring, decryption, decompression, unpacking, distribution, reassignment, compilation, etc., in order to make them directly readable, interpretable, and/or executable by a computing device and/or other machine. For example, the machine readable instructions may be stored in multiple parts, which are individually compressed, encrypted, and/or stored on separate computing devices, wherein the parts when decrypted, decompressed, and/or combined form a set of computer-executable and/or machine executable instructions that implement one or more functions and/or operations that may together form a program such as that described herein.

In another example, the machine readable instructions may be stored in a state in which they may be read by programmable circuitry, but require addition of a library (e.g., a dynamic link library (DLL)), a software development kit (SDK), an application programming interface (API), etc., in order to execute the machine-readable instructions on a particular computing device or other device. In another example, the machine readable instructions may need to be configured (e.g., settings stored, data input, network addresses recorded, etc.) before the machine readable instructions and/or the corresponding program(s) can be executed in whole or in part. Thus, machine readable, computer readable and/or machine readable media, as used herein, may include instructions and/or program(s) regardless of the particular format or state of the machine readable instructions and/or program(s).

The machine readable instructions described herein can be represented by any past, present, or future instruction language, scripting language, programming language, etc. For example, the machine readable instructions may be represented using any of the following languages: C, C++, Java, C-Sharp, Perl, Python, JavaScript, HyperText Markup Language (HTML), Structured Query Language (SQL), Swift, etc.

As mentioned above, the example operations of FIG. 4 may be implemented using executable instructions (e.g., computer readable and/or machine readable instructions) stored on one or more non-transitory computer readable and/or machine readable media. As used herein, the terms non-transitory computer readable medium, non-transitory computer readable storage medium, non-transitory machine readable medium, and/or non-transitory machine readable storage medium are expressly defined to include any type of computer readable storage device and/or storage disk and to exclude propagating signals and to exclude transmission media. Examples of such non-transitory computer readable medium, non-transitory computer readable storage medium, non-transitory machine readable medium, and/or non-transitory machine readable storage medium include optical storage devices, magnetic storage devices, an HDD, a flash memory, a read-only memory (ROM), a CD, a DVD, a cache, a RAM of any type, a register, and/or any other storage device or storage disk in which information is stored for any duration (e.g., for extended time periods, permanently, for brief instances, for temporarily buffering, and/or for caching of the information). As used herein, the terms “non-transitory computer readable storage device” and “non-transitory machine readable storage device” are defined to include any physical (mechanical, magnetic and/or electrical) hardware to retain information for a time period, but to exclude propagating signals and to exclude transmission media. Examples of non-transitory computer readable storage devices and/or non-transitory machine readable storage devices include random access memory of any type, read only memory of any type, solid state memory, flash memory, optical discs, magnetic disks, disk drives, and/or redundant array of independent disks (RAID) systems. As used herein, the term “device” refers to physical structure such as mechanical and/or electrical equipment, hardware, and/or circuitry that may or may not be configured by computer readable instructions, machine readable instructions, etc., and/or manufactured to execute computer-readable instructions, machine-readable instructions, etc.

FIG. 4 is a flowchart representative of example machine readable instructions and/or example operations 400 that may be executed, instantiated, and/or performed by programmable circuitry to delete or erase and prevent the recovery of data stored in an example memory array (e.g., the example memory array 104). The example machine-readable instructions and/or the example operations 400 of FIG. 4 begin at block 402, at which the example interface circuitry 302 receives an instruction to zeroize a memory array.

At block 404, the example selection row word line driver circuitry 304 raises one or more selection row world line(s) 112 to a supply voltage (e.g., 1.8 volts). At block 406, the example programming row word line driver circuitry 306 raises one or more programming row world line(s) 116 to a zeroization voltage (e.g., 5 volts) to cause dielectric breakdown of a gate oxide in memory transistor(s) 114 associated with the programming row word line(s) 116. In some examples, the voltages applies at blocks 404 and 406 are applied to all of the associated transistors in the corresponding word lines 112, 116 regardless of the logical value of the different ones of the memory cells prior to receiving the instructions at block 402. That is, in this example, there is no need to identify and/or isolate the memory cells that need to be switched to a value of 1. Instead, every memory cell can be provided the needed voltage to switch it to a 1, thereby significantly simplifying the zeroization process relative to known efuse techniques for zeroization.

At block 408, the example verification circuitry 308 determines whether additional memory cells 106 are to be zeroized. In some examples, this is based on a verification process that confirms whether dielectric breakdown was achieved at block 408, thereby switching the associated memory cell 106 to a logical value of 1. Additionally or alternatively, in some examples, the verification circuitry 308 identifies other memory cells 106 to be zeroized that were not involved in previous iterations of block 406 and 408. If the example verification circuitry 308 determines that additional memory cells 106 are to be zeroized, control returns to block 406. Otherwise, the example operations 400 of FIG. 4 end.

FIG. 5 is a block diagram of an example programmable circuitry platform 500 structured to execute and/or instantiate the example machine-readable instructions and/or the example operations of FIG. 4 to implement the controller of FIG. 3. The programmable circuitry platform 500 can be, for example, a server, a personal computer, a workstation, a self-learning machine (e.g., a neural network), a mobile device (e.g., a cell phone, a smart phone, a tablet such as an iPad™), a personal digital assistant (PDA), an Internet appliance, a DVD player, a CD player, a digital video recorder, a Blu-ray player, a gaming console, a personal video recorder, a set top box, a headset (e.g., an augmented reality (AR) headset, a virtual reality (VR) headset, etc.) or other wearable device, or any other type of computing and/or electronic device.

The programmable circuitry platform 500 of the illustrated example includes programmable circuitry 512. The programmable circuitry 512 of the illustrated example is hardware. For example, the programmable circuitry 512 can be implemented by one or more integrated circuits, logic circuits, FPGAs, microprocessors, CPUs, GPUs, DSPs, and/or microcontrollers from any desired family or manufacturer. The programmable circuitry 512 may be implemented by one or more semiconductor based (e.g., silicon based) devices. In this example, the programmable circuitry 512 implements the example interface circuitry 302, the example selection row word line driver circuitry 304, the example programming row word line driver circuitry 306, and the example verification circuitry 308.

The programmable circuitry 512 of the illustrated example includes a local memory 513 (e.g., a cache, registers, etc.). The programmable circuitry 512 of the illustrated example is in communication with main memory 514, 516, which includes a volatile memory 514 and a non-volatile memory 516, by a bus 518. The volatile memory 514 may be implemented by Synchronous Dynamic Random Access Memory (SDRAM), Dynamic Random Access Memory (DRAM), RAMBUS® Dynamic Random Access Memory (RDRAM®), and/or any other type of RAM device. The non-volatile memory 516 may be implemented by flash memory and/or any other desired type of memory device. Access to the main memory 514, 516 of the illustrated example is controlled by a memory controller 517. In some examples, the memory controller 517 may be implemented by one or more integrated circuits, logic circuits, microcontrollers from any desired family or manufacturer, or any other type of circuitry to manage the flow of data going to and from the main memory 514, 516.

The programmable circuitry platform 500 of the illustrated example also includes interface circuitry 520. The interface circuitry 520 may be implemented by hardware in accordance with any type of interface standard, such as an Ethernet interface, a universal serial bus (USB) interface, a Bluetooth® interface, a near field communication (NFC) interface, a Peripheral Component Interconnect (PCI) interface, and/or a Peripheral Component Interconnect Express (PCIe) interface.

In the illustrated example, one or more input devices 522 are connected to the interface circuitry 520. The input device(s) 522 permit(s) a user (e.g., a human user, a machine user, etc.) to enter data and/or commands into the programmable circuitry 512. The input device(s) 522 can be implemented by, for example, an audio sensor, a microphone, a camera (still or video), a keyboard, a button, a mouse, a touchscreen, a trackpad, a trackball, an isopoint device, and/or a voice recognition system.

One or more output devices 524 are also connected to the interface circuitry 520 of the illustrated example. The output device(s) 524 can be implemented, for example, by display devices (e.g., a light emitting diode (LED), an organic light emitting diode (OLED), a liquid crystal display (LCD), a cathode ray tube (CRT) display, an in-place switching (IPS) display, a touchscreen, etc.), a tactile output device, a printer, and/or speaker. The interface circuitry 520 of the illustrated example, thus, typically includes a graphics driver card, a graphics driver chip, and/or graphics processor circuitry such as a GPU.

The interface circuitry 520 of the illustrated example also includes a communication device such as a transmitter, a receiver, a transceiver, a modem, a residential gateway, a wireless access point, and/or a network interface to facilitate exchange of data with external machines (e.g., computing devices of any kind) by a network 526. The communication can be by, for example, an Ethernet connection, a digital subscriber line (DSL) connection, a telephone line connection, a coaxial cable system, a satellite system, a beyond-line-of-sight wireless system, a line-of-sight wireless system, a cellular telephone system, an optical connection, etc.

The programmable circuitry platform 500 of the illustrated example also includes one or more mass storage discs or devices 528 to store firmware, software, and/or data. Examples of such mass storage discs or devices 528 include magnetic storage devices (e.g., floppy disk, drives, HDDs, etc.), optical storage devices (e.g., Blu-ray disks, CDs, DVDs, etc.), RAID systems, and/or solid-state storage discs or devices such as flash memory devices and/or SSDs.

The machine readable instructions 532, which may be implemented by the machine readable instructions of FIG. 4, may be stored in the mass storage device 528, in the volatile memory 514, in the non-volatile memory 516, and/or on at least one non-transitory computer readable storage medium such as a CD or DVD which may be removable.

FIG. 6 is a block diagram of an example implementation of the programmable circuitry 512 of FIG. 5. In this example, the programmable circuitry 512 of FIG. 5 is implemented by a microprocessor 600. For example, the microprocessor 600 may be a general-purpose microprocessor (e.g., general-purpose microprocessor circuitry). The microprocessor 600 executes some or all of the machine-readable instructions of the flowchart of FIG. 4 to effectively instantiate the circuitry of FIG. 3 as logic circuits to perform operations corresponding to those machine readable instructions. In some such examples, the circuitry of FIG. 3 is instantiated by the hardware circuits of the microprocessor 600 in combination with the machine-readable instructions. For example, the microprocessor 600 may be implemented by multi-core hardware circuitry such as a CPU, a DSP, a GPU, an XPU, etc. Although it may include any number of example cores 602 (e.g., 1 core), the microprocessor 600 of this example is a multi-core semiconductor device including N cores. The cores 602 of the microprocessor 600 may operate independently or may cooperate to execute machine readable instructions. For example, machine code corresponding to a firmware program, an embedded software program, or a software program may be executed by one of the cores 602 or may be executed by multiple ones of the cores 602 at the same or different times. In some examples, the machine code corresponding to the firmware program, the embedded software program, or the software program is split into threads and executed in parallel by two or more of the cores 602. The software program may correspond to a portion or all of the machine readable instructions and/or operations represented by the flowchart of FIG. 4.

The cores 602 may communicate by a first example bus 604. In some examples, the first bus 604 may be implemented by a communication bus to effectuate communication associated with one(s) of the cores 602. For example, the first bus 604 may be implemented by at least one of an Inter-Integrated Circuit (I2C) bus, a Serial Peripheral Interface (SPI) bus, a PCI bus, or a PCIe bus. Additionally or alternatively, the first bus 604 may be implemented by any other type of computing or electrical bus. The cores 602 may obtain data, instructions, and/or signals from one or more external devices by example interface circuitry 606. The cores 602 may output data, instructions, and/or signals to the one or more external devices by the interface circuitry 606. Although the cores 602 of this example include example local memory 620 (e.g., Level 1 (L1) cache that may be split into an L1 data cache and an L1 instruction cache), the microprocessor 600 also includes example shared memory 610 that may be shared by the cores (e.g., Level 3 (L2 cache)) for high-speed access to data and/or instructions. Data and/or instructions may be transferred (e.g., shared) by writing to and/or reading from the shared memory 610. The local memory 620 of each of the cores 602 and the shared memory 610 may be part of a hierarchy of storage devices including multiple levels of cache memory and the main memory (e.g., the main memory 514, 516 of FIG. 5). Typically, higher levels of memory in the hierarchy exhibit lower access time and have smaller storage capacity than lower levels of memory. Changes in the various levels of the cache hierarchy are managed (e.g., coordinated) by a cache coherency policy.

Each core 602 may be referred to as a CPU, DSP, GPU, etc., or any other type of hardware circuitry. Each core 602 includes control unit circuitry 614, arithmetic and logic (AL) circuitry (sometimes referred to as an ALU) 616, a plurality of registers 618, the local memory 620, and a second example bus 622. Other structures may be present. For example, each core 602 may include vector unit circuitry, single instruction multiple data (SIMD) unit circuitry, load/store unit (LSU) circuitry, branch/jump unit circuitry, floating-point unit (FPU) circuitry, etc. The control unit circuitry 614 includes semiconductor-based circuits structured to control (e.g., coordinate) data movement within the corresponding core 602. The AL circuitry 616 includes semiconductor-based circuits structured to perform one or more mathematic and/or logic operations on the data within the corresponding core 602. The AL circuitry 616 of some examples performs integer based operations. In other examples, the AL circuitry 616 also performs floating-point operations. In yet other examples, the AL circuitry 616 may include first AL circuitry that performs integer-based operations and second AL circuitry that performs floating-point operations. In some examples, the AL circuitry 616 may be referred to as an Arithmetic Logic Unit (ALU).

The registers 618 are semiconductor-based structures to store data and/or instructions such as results of one or more of the operations performed by the AL circuitry 616 of the corresponding core 602. For example, the registers 618 may include vector register(s), SIMD register(s), general-purpose register(s), flag register(s), segment register(s), machine-specific register(s), instruction pointer register(s), control register(s), debug register(s), memory management register(s), machine check register(s), etc. The registers 618 may be arranged in a bank as shown in FIG. 6. Alternatively, the registers 618 may be organized in any other arrangement, format, or structure, such as by being distributed throughout the core 602 to shorten access time. The second bus 622 may be implemented by at least one of an I2C bus, a SPI bus, a PCI bus, or a PCIe bus.

Each core 602 and/or, more generally, the microprocessor 600 may include additional and/or alternate structures to those shown and described above. For example, one or more clock circuits, one or more power supplies, one or more power gates, one or more cache home agents (CHAs), one or more converged/common mesh stops (CMSs), one or more shifters (e.g., barrel shifter(s)) and/or other circuitry may be present. The microprocessor 600 is a semiconductor device fabricated to include many transistors interconnected to implement the structures described above in one or more integrated circuits (ICs) contained in one or more packages.

The microprocessor 600 may include and/or cooperate with one or more accelerators (e.g., acceleration circuitry, hardware accelerators, etc.). In some examples, accelerators are implemented by logic circuitry to perform certain tasks more quickly and/or efficiently than can be done by a general-purpose processor. Examples of accelerators include ASICs and FPGAs such as those discussed herein. A GPU, DSP and/or other programmable device can also be an accelerator. Accelerators may be on-board the microprocessor 600, in the same chip package as the microprocessor 600 and/or in one or more separate packages from the microprocessor 600.

FIG. 7 is a block diagram of another example implementation of the programmable circuitry 512 of FIG. 5. In this example, the programmable circuitry 512 is implemented by FPGA circuitry 700. For example, the FPGA circuitry 700 may be implemented by an FPGA. The FPGA circuitry 700 can be used, for example, to perform operations that could otherwise be performed by the example microprocessor 600 of FIG. 6 executing corresponding machine readable instructions. However, once configured, the FPGA circuitry 700 instantiates the operations and/or functions corresponding to the machine readable instructions in hardware and, thus, can often execute the operations/functions faster than they could be performed by a general-purpose microprocessor executing the corresponding software.

More specifically, in contrast to the microprocessor 600 of FIG. 6 described above (which is a general purpose device that may be programmed to execute some or all of the machine readable instructions represented by the flowchart of FIG. 4 but whose interconnections and logic circuitry are fixed once fabricated), the FPGA circuitry 700 of the example of FIG. 7 includes interconnections and logic circuitry that may be configured, structured, programmed, and/or interconnected in different ways after fabrication to instantiate, for example, some or all of the operations/functions corresponding to the machine readable instructions represented by the flowchart of FIG. 4. In particular, the FPGA circuitry 700 may be thought of as an array of logic gates, interconnections, and switches. The switches can be programmed to change how the logic gates are interconnected by the interconnections, effectively forming one or more dedicated logic circuits (unless and until the FPGA circuitry 700 is reprogrammed). The configured logic circuits enable the logic gates to cooperate in different ways to perform different operations on data received by input circuitry. Those operations may correspond to some or all of the instructions (e.g., the software and/or firmware) represented by the flowchart of FIG. 4. As such, the FPGA circuitry 700 may be configured and/or structured to effectively instantiate some or all of the operations/functions corresponding to the machine readable instructions of the flowchart of FIG. 4 as dedicated logic circuits to perform the operations/functions corresponding to those software instructions in a dedicated manner analogous to an ASIC. Therefore, the FPGA circuitry 700 may perform the operations/functions corresponding to the some or all of the machine readable instructions of FIG. 4 faster than the general-purpose microprocessor can execute the same.

In the example of FIG. 7, the FPGA circuitry 700 is configured and/or structured in response to being programmed (and/or reprogrammed one or more times) based on a binary file. In some examples, the binary file may be compiled and/or generated based on instructions in a hardware description language (HDL) such as Lucid, Very High Speed Integrated Circuits (VHSIC) Hardware Description Language (VHDL), or Verilog. For example, a user (e.g., a human user, a machine user, etc.) may write code or a program corresponding to one or more operations/functions in an HDL; the code/program may be translated into a low-level language as needed; and the code/program (e.g., the code/program in the low-level language) may be converted (e.g., by a compiler, a software application, etc.) into the binary file. In some examples, the FPGA circuitry 700 of FIG. 7 may access and/or load the binary file to cause the FPGA circuitry 700 of FIG. 7 to be configured and/or structured to perform the one or more operations/functions. For example, the binary file may be implemented by a bit stream (e.g., one or more computer-readable bits, one or more machine-readable bits, etc.), data (e.g., computer-readable data, machine-readable data, etc.), and/or machine-readable instructions accessible to the FPGA circuitry 700 of FIG. 7 to cause configuration and/or structuring of the FPGA circuitry 700 of FIG. 7, or portion(s) thereof.

In some examples, the binary file is compiled, generated, transformed, and/or otherwise output from a uniform software platform utilized to program FPGAs. For example, the uniform software platform may translate first instructions (e.g., code or a program) that correspond to one or more operations/functions in a high-level language (e.g., C, C++, Python, etc.) into second instructions that correspond to the one or more operations/functions in an HDL. In some such examples, the binary file is compiled, generated, and/or otherwise output from the uniform software platform based on the second instructions. In some examples, the FPGA circuitry 700 of FIG. 7 may access and/or load the binary file to cause the FPGA circuitry 700 of FIG. 7 to be configured and/or structured to perform the one or more operations/functions. For example, the binary file may be implemented by a bit stream (e.g., one or more computer-readable bits, one or more machine-readable bits, etc.), data (e.g., computer-readable data, machine-readable data, etc.), and/or machine-readable instructions accessible to the FPGA circuitry 700 of FIG. 7 to cause configuration and/or structuring of the FPGA circuitry 700 of FIG. 7, or portion(s) thereof.

The FPGA circuitry 700 of FIG. 7, includes example input/output (I/O) circuitry 702 to obtain and/or output data to/from example configuration circuitry 704 and/or external hardware 706. For example, the configuration circuitry 704 may be implemented by interface circuitry that may obtain a binary file, which may be implemented by a bit stream, data, and/or machine-readable instructions, to configure the FPGA circuitry 700, or portion(s) thereof. In some such examples, the configuration circuitry 704 may obtain the binary file from a user, a machine (e.g., hardware circuitry (e.g., programmable or dedicated circuitry) that may implement an Artificial Intelligence/Machine Learning (AI/ML) model to generate the binary file), etc., and/or any combination(s) thereof). In some examples, the external hardware 706 may be implemented by external hardware circuitry. For example, the external hardware 706 may be implemented by the microprocessor 600 of FIG. 6.

The FPGA circuitry 700 also includes an array of example logic gate circuitry 708, a plurality of example configurable interconnections 710, and example storage circuitry 712. The logic gate circuitry 708 and the configurable interconnections 710 are configurable to instantiate one or more operations/functions that may correspond to at least some of the machine readable instructions of FIG. 4 and/or other desired operations. The logic gate circuitry 708 shown in FIG. 7 is fabricated in blocks or groups. Each block includes semiconductor-based electrical structures that may be configured into logic circuits. In some examples, the electrical structures include logic gates (e.g., And gates, Or gates, Nor gates, etc.) that provide basic building blocks for logic circuits. Electrically controllable switches (e.g., transistors) are present within each of the logic gate circuitry 708 to enable configuration of the electrical structures and/or the logic gates to form circuits to perform desired operations/functions. The logic gate circuitry 708 may include other electrical structures such as look-up tables (LUTs), registers (e.g., flip-flops or latches), multiplexers, etc.

The configurable interconnections 710 of the illustrated example are conductive pathways, traces, vias, or the like that may include electrically controllable switches (e.g., transistors) whose state can be changed by programming (e.g., using an HDL instruction language) to activate or deactivate one or more connections between one or more of the logic gate circuitry 708 to program desired logic circuits.

The storage circuitry 712 of the illustrated example is structured to store result(s) of the one or more of the operations performed by corresponding logic gates. The storage circuitry 712 may be implemented by registers or the like. In the illustrated example, the storage circuitry 712 is distributed amongst the logic gate circuitry 708 to facilitate access and increase execution speed.

The example FPGA circuitry 700 of FIG. 7 also includes example dedicated operations circuitry 714. In this example, the dedicated operations circuitry 714 includes special purpose circuitry 716 that may be invoked to implement commonly used functions to avoid the need to program those functions in the field. Examples of such special purpose circuitry 716 include memory (e.g., DRAM) controller circuitry, PCIe controller circuitry, clock circuitry, transceiver circuitry, memory, and multiplier-accumulator circuitry. Other types of special purpose circuitry may be present. In some examples, the FPGA circuitry 700 may also include example general purpose programmable circuitry 718 such as an example CPU 720 and/or an example DSP 722. Other general purpose programmable circuitry 718 may additionally or alternatively be present such as a GPU, an XPU, etc., that can be programmed to perform other operations.

Although FIGS. 6 and 7 illustrate two example implementations of the programmable circuitry 512 of FIG. 5, many other approaches are contemplated. For example, FPGA circuitry may include an on-board CPU, such as one or more of the example CPU 720 of FIG. 6. Therefore, the programmable circuitry 512 of FIG. 5 may additionally be implemented by combining at least the example microprocessor 600 of FIG. 6 and the example FPGA circuitry 700 of FIG. 7. In some such hybrid examples, one or more cores 602 of FIG. 6 may execute a first portion of the machine readable instructions represented by the flowchart of FIG. 4 to perform first operation(s)/function(s), the FPGA circuitry 700 of FIG. 7 may be configured and/or structured to perform second operation(s)/function(s) corresponding to a second portion of the machine readable instructions represented by the flowchart of FIG. 4, and/or an ASIC may be configured and/or structured to perform third operation(s)/function(s) corresponding to a third portion of the machine readable instructions represented by the flowchart of FIG. 4.

It should be understood that some or all of the circuitry of FIG. 3 may, thus, be instantiated at the same or different times. For example, same and/or different portion(s) of the microprocessor 600 of FIG. 6 may be programmed to execute portion(s) of machine-readable instructions at the same and/or different times. In some examples, same and/or different portion(s) of the FPGA circuitry 700 of FIG. 7 may be configured and/or structured to perform operations/functions corresponding to portion(s) of machine-readable instructions at the same and/or different times.

In some examples, some or all of the circuitry of FIG. 3 may be instantiated, for example, in one or more threads executing concurrently and/or in series. For example, the microprocessor 600 of FIG. 6 may execute machine readable instructions in one or more threads executing concurrently and/or in series. In some examples, the FPGA circuitry 700 of FIG. 7 may be configured and/or structured to carry out operations/functions concurrently and/or in series. Moreover, in some examples, some or all of the circuitry of FIG. 3 may be implemented within one or more virtual machines and/or containers executing on the microprocessor 600 of FIG. 6.

In some examples, the programmable circuitry 512 of FIG. 5 may be in one or more packages. For example, the microprocessor 600 of FIG. 6 and/or the FPGA circuitry 700 of FIG. 7 may be in one or more packages. In some examples, an XPU may be implemented by the programmable circuitry 512 of FIG. 5, which may be in one or more packages. For example, the XPU may include a CPU (e.g., the microprocessor 600 of FIG. 6, the CPU 720 of FIG. 7, etc.) in one package, a DSP (e.g., the DSP 722 of FIG. 7) in another package, a GPU in yet another package, and an FPGA (e.g., the FPGA circuitry 700 of FIG. 7) in still yet another package.

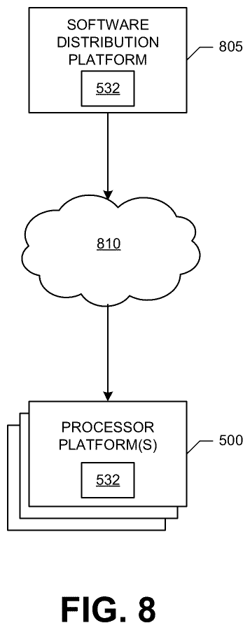

A block diagram illustrating an example software distribution platform 805 to distribute software such as the example machine readable instructions 532 of FIG. 5 to other hardware devices (e.g., hardware devices owned and/or operated by third parties from the owner and/or operator of the software distribution platform) is illustrated in FIG. 8. The example software distribution platform 805 may be implemented by any computer server, data facility, cloud service, etc., capable of storing and transmitting software to other computing devices. The third parties may be customers of the entity owning and/or operating the software distribution platform 805. For example, the entity that owns and/or operates the software distribution platform 805 may be a developer, a seller, and/or a licensor of software such as the example machine readable instructions 532 of FIG. 5. The third parties may be consumers, users, retailers, OEMs, etc., who purchase and/or license the software for use and/or re-sale and/or sub-licensing. In the illustrated example, the software distribution platform 805 includes one or more servers and one or more storage devices. The storage devices store the machine readable instructions 532, which may correspond to the example machine readable instructions of FIG. 4, as described above. The one or more servers of the example software distribution platform 805 are in communication with an example network 810, which may correspond to any one or more of the Internet and/or any of the example networks described above. In some examples, the one or more servers are responsive to requests to transmit the software to a requesting party as part of a commercial transaction. Payment for the delivery, sale, and/or license of the software may be handled by the one or more servers of the software distribution platform and/or by a third party payment entity. The servers enable purchasers and/or licensors to download the machine readable instructions 532 from the software distribution platform 805. For example, the software, which may correspond to the example machine readable instructions of FIG. 4, may be downloaded to the example programmable circuitry platform 500, which is to execute the machine readable instructions 532 to implement the controller. In some examples, one or more servers of the software distribution platform 805 periodically offer, transmit, and/or force updates to the software (e.g., the example machine readable instructions 532 of FIG. 5) to ensure improvements, patches, updates, etc., are distributed and applied to the software at the end user devices. Although referred to as software above, the distributed “software” could alternatively be firmware.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities, etc., the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities, etc., the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

Notwithstanding the foregoing, in the case of referencing a semiconductor device (e.g., a transistor), a semiconductor die containing a semiconductor device, and/or an integrated circuit (IC) package containing a semiconductor die during fabrication or manufacturing, “above” is not with reference to Earth, but instead is with reference to an underlying substrate on which relevant components are fabricated, assembled, mounted, supported, or otherwise provided. Thus, as used herein and unless otherwise stated or implied from the context, a first component within a semiconductor die (e.g., a transistor or other semiconductor device) is “above” a second component within the semiconductor die when the first component is farther away from a substrate (e.g., a semiconductor wafer) during fabrication/manufacturing than the second component on which the two components are fabricated or otherwise provided. Similarly, unless otherwise stated or implied from the context, a first component within an IC package (e.g., a semiconductor die) is “above” a second component within the IC package during fabrication when the first component is farther away from a printed circuit board (PCB) to which the IC package is to be mounted or attached. It is to be understood that semiconductor devices are often used in orientation different than their orientation during fabrication. Thus, when referring to a semiconductor device (e.g., a transistor), a semiconductor die containing a semiconductor device, and/or an integrated circuit (IC) package containing a semiconductor die during use, the definition of “above” in the preceding paragraph (i.e., the term “above” describes the relationship of two parts relative to Earth) will likely govern based on the usage context.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/−10% unless otherwise specified herein.

As used herein “substantially real time” refers to occurrence in a near instantaneous manner recognizing there may be real world delays for computing time, transmission, etc. Thus, unless otherwise specified, “substantially real time” refers to real time+1 second.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “programmable circuitry” is defined to include (i) one or more special purpose electrical circuits (e.g., an application specific circuit (ASIC)) structured to perform specific operation(s) and including one or more semiconductor-based logic devices (e.g., electrical hardware implemented by one or more transistors), and/or (ii) one or more general purpose semiconductor-based electrical circuits programmable with instructions to perform specific functions(s) and/or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations and/or functions, Field Programmable Gate Arrays (FPGAs) that may be programmed with second instructions to cause configuration and/or structuring of the FPGAs to instantiate one or more operations and/or functions corresponding to the first instructions, Graphics Processor Units (GPUs) that may execute first instructions to perform one or more operations and/or functions, Digital Signal Processors (DSPs) that may execute first instructions to perform one or more operations and/or functions, XPUs, Network Processing Units (NPUs) one or more microcontrollers that may execute first instructions to perform one or more operations and/or functions and/or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example an integrated circuit may be implemented as one or more of an ASIC, an FPGA, a chip, a microchip, programmable circuitry, a semiconductor substrate coupling multiple circuit elements, a system on chip (SoC), etc.

From the foregoing, it will be appreciated that example systems, apparatus, articles of manufacture, and methods have been disclosed that enable the zeroization of read-only memory based on antifuse elements within the memory rather than efuse technology used in the past. Antifuse technology significantly reduces yield loss relative to efuse technology. Furthermore, example disclosed herein enable multi-pulse programming, which enables multiple (e.g., every) bit in the memory to be assigned the same value (e.g., a logic value of 1) for zeroization regardless of whether a given bit has already been assigned the value. As such, examples disclosed herein significantly reduce the complexity relative to existing zeroization techniques that require the identification and isolation of particular memory cells that have values that need to be switched. Another advantage of example disclosed herein is that there is no visible impact to the circuitry resulting from the disclosed zeroization process, thereby preventing the possibility of reverse engineering information about the originally stored data prior to zeroization. As such, disclosed systems, apparatus, articles of manufacture, and methods are accordingly directed to one or more improvement(s) in the operation of a machine such as a computer or other electronic and/or mechanical device.

Further examples and combinations thereof include the following:

Example 1 includes an apparatus comprising machine readable instructions, and at least one programmable circuit to at least one of instantiate or execute the machine readable instructions to obtain an instruction to zeroize a memory array, and cause a voltage to be applied across a plurality of transistors associated with a plurality of memory cells in the memory array, the voltage to set the plurality of memory cells to a same logical value, the voltage applied across the transistors regardless of logical values of the plurality of memory cells prior to receiving the instruction to zeroize the memory array.

Example 2 includes any preceding clause(s) of example 1, wherein the voltage is a first voltage, and the transistors are first transistors, one or more of the at least one programmable circuit to cause a second voltage to be applied to second transistors associated with the plurality of memory cells, the second transistors electrically coupling the first transistors to corresponding bit lines of the memory array.

Example 3 includes any preceding clause(s) of any one or more of examples 1-2, wherein the first voltage is higher than the second voltage.

Example 4 includes any preceding clause(s) of any one or more of examples 1-3, wherein the first voltage is to cause dielectric breakdown of a gate oxide in the first transistors.

Example 5 includes any preceding clause(s) of any one or more of examples 1-4, wherein the gate oxide is a first gate oxide having a first thickness, the second transistors including a second gate oxide having a second thickness, the second thickness greater than the first thickness such that the second gate oxide does not undergo dielectric breakdown.

Example 6 includes any preceding clause(s) of any one or more of examples 1-5, wherein the same logical value is a value of 1.

Example 7 includes any preceding clause(s) of any one or more of examples 1-6, wherein the memory array is associated with one-time programmable read-only memory.

Example 8 includes any preceding clause(s) of any one or more of examples 1-7, wherein the voltage is applied using a current of less than 1 milliamp.

Example 9 includes a non-transitory machine readable storage medium comprising instructions to cause at least one programmable circuit to at least obtain an instruction to zeroize a memory array, and cause a voltage to be applied across a plurality of transistors associated with a plurality of memory cells in the memory array, the voltage to set the plurality of memory cells to a same logical value, the voltage applied across the transistors regardless of the logical values of the plurality of memory cells prior to receiving the instruction to zeroize the memory array.

Example 10 includes any preceding clause(s) of example 9, wherein the voltage is a first voltage, and the transistors are first transistors, the instructions to cause one or more of the at least one programmable circuit to cause a second voltage to be applied to second transistors associated with the plurality of memory cells, the second transistors electrically coupling the first transistors to corresponding bit lines of the memory array.

Example 11 includes any preceding clause(s) of any one or more of examples 9-10, wherein the first voltage is higher than the second voltage.

Example 12 includes any preceding clause(s) of any one or more of examples 9-11, wherein the first voltage is to cause dielectric breakdown of a gate oxide in the first transistors.

Example 13 includes any preceding clause(s) of any one or more of examples 9-12, wherein the gate oxide is a first gate oxide having a first thickness, the second transistors including a second gate oxide having a second thickness, the second thickness greater than the first thickness such that the second gate oxide does not undergo dielectric breakdown.

Example 14 includes any preceding clause(s) of any one or more of examples 9-13, wherein the same logical value is a value of 1.

Example 15 includes any preceding clause(s) of any one or more of examples 9-14, wherein the memory array is associated with one-time programmable read-only memory.

Example 16 includes any preceding clause(s) of any one or more of examples 9-15, wherein the voltage is applied using a current of less than 1 milliamp.

Example 17 includes a method comprising obtaining an instruction to zeroize a memory array, and causing, based on at least one processor circuit executing instructions, a voltage to be applied across a plurality of transistors associated with a plurality of memory cells in the memory array, the voltage to set the plurality of memory cells to a same logical value, the voltage applied across the transistors regardless of the logical values of the plurality of memory cells prior to receiving the instruction to zeroize the memory array.

Example 18 includes any preceding clause(s) of example 17, wherein the voltage is a first voltage, and the transistors are first transistors, the method further including causing a second voltage to be applied to second transistors associated with the plurality of memory cells, the second transistors electrically coupling the first transistors to corresponding bit lines of the memory array.

Example 19 includes any preceding clause(s) of any one or more of examples 17-18, wherein the first voltage is to cause dielectric breakdown of a gate oxide in the first transistors.

Example 20 includes any preceding clause(s) of any one or more of examples 17-19, wherein the voltage is applied using a current of less than 1 milliamp.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

What is claimed is:

1. An apparatus comprising:
machine readable instructions; and
at least one programmable circuit to at least one of instantiate or execute the machine readable instructions to:
obtain an instruction to zeroize a memory array; and
cause a voltage to be applied across a plurality of transistors associated with a plurality of memory cells in the memory array, the voltage to set the plurality of memory cells to a same logical value, the voltage applied across the transistors regardless of logical values of the plurality of memory cells prior to receiving the instruction to zeroize the memory array.

2. The apparatus of claim 1, wherein the voltage is a first voltage, and the transistors are first transistors, one or more of the at least one programmable circuit to cause a second voltage to be applied to second transistors associated with the plurality of memory cells, the second transistors electrically coupling the first transistors to corresponding bit lines of the memory array.

3. The apparatus of claim 2, wherein the first voltage is higher than the second voltage.

4. The apparatus of claim 2, wherein the first voltage is to cause dielectric breakdown of a gate oxide in the first transistors.

5. The apparatus of claim 4, wherein the gate oxide is a first gate oxide having a first thickness, the second transistors including a second gate oxide having a second thickness, the second thickness greater than the first thickness such that the second gate oxide does not undergo dielectric breakdown.

6. The apparatus of claim 1, wherein the same logical value is a value of 1.

7. The apparatus of claim 1, wherein the memory array is associated with one-time programmable read-only memory.

8. The apparatus of claim 1, wherein the voltage is applied using a current of less than 1 milliamp.

9. A non-transitory machine readable storage medium comprising instructions to cause at least one programmable circuit to at least:
obtain an instruction to zeroize a memory array; and
cause a voltage to be applied across a plurality of transistors associated with a plurality of memory cells in the memory array, the voltage to set the plurality of memory cells to a same logical value, the voltage applied across the transistors regardless of the logical values of the plurality of memory cells prior to receiving the instruction to zeroize the memory array.

10. The non-transitory machine readable storage medium of claim 9, wherein the voltage is a first voltage, and the transistors are first transistors, the instructions to cause one or more of the at least one programmable circuit to cause a second voltage to be applied to second transistors associated with the plurality of memory cells, the second transistors electrically coupling the first transistors to corresponding bit lines of the memory array.

11. The non-transitory machine readable storage medium of claim 10, wherein the first voltage is higher than the second voltage.

12. The non-transitory machine readable storage medium of claim 10, wherein the first voltage is to cause dielectric breakdown of a gate oxide in the first transistors.

13. The non-transitory machine readable storage medium of claim 12, wherein the gate oxide is a first gate oxide having a first thickness, the second transistors including a second gate oxide having a second thickness, the second thickness greater than the first thickness such that the second gate oxide does not undergo dielectric breakdown.

14. The non-transitory machine readable storage medium of claim 9, wherein the same logical value is a value of 1.

15. The non-transitory machine readable storage medium of claim 9, wherein the memory array is associated with one-time programmable read-only memory.

16. The non-transitory machine readable storage medium of claim 9, wherein the voltage is applied using a current of less than 1 milliamp.

17. A method comprising:
obtaining an instruction to zeroize a memory array; and
causing, based on at least one processor circuit executing instructions, a voltage to be applied across a plurality of transistors associated with a plurality of memory cells in the memory array, the voltage to set the plurality of memory cells to a same logical value, the voltage applied across the transistors regardless of the logical values of the plurality of memory cells prior to receiving the instruction to zeroize the memory array.

18. The method of claim 17, wherein the voltage is a first voltage, and the transistors are first transistors, the method further including causing a second voltage to be applied to second transistors associated with the plurality of memory cells, the second transistors electrically coupling the first transistors to corresponding bit lines of the memory array.

19. The method of claim 18, wherein the first voltage is to cause dielectric breakdown of a gate oxide in the first transistors.

20. The method of claim 17, wherein the voltage is applied using a current of less than 1 milliamp.
